(19) United States
(12) Patent Application Publication
(10) Pub. No.: US 2008/0103706 A1
(43) Pub. Date: May 1, 2008

(54) SYSTEM AND METHOD FOR TESTING LEDS ON A MOTHERBOARD

(75) Inventors: KUAN-LIN WU, Tu-Cheng (TW); WEI-YUAN CHEN, Tu-Cheng (TW)

Correspondence Address: PCE INDUSTRY, INC.;ATT. CHENG-JU CHIANG J, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/752,936

(22) Filed: May 24, 2007

(30) Foreign Application Priority Data
Oct. 27, 2006 (CN) 200610063337.2

(51) Int. Cl. G01R 31/26

(52) U.S. Cl. 702/58

(57) ABSTRACT

An exemplary system for testing light-emitting diodes (LEDs) on a motherboard is provided. The system typically includes: an insulating plate covered on the motherboard, configured with optical fibers for inducing beams sourced from the LEDs and transmitting the beams to a circuit board; the circuit board includes at least one photoresistor, configured for sensing the beams to obtain influence values; a computer configured for detecting whether the influence values are within a photosensitive range when the LEDs are powered on, for detecting whether resistance values of all the given number of at least one photoresistor are equal to a dark resistance when the LEDs are powered off and for reporting test results. A related method is also provided.

### BACKGROUND OF THE INVENTION

1. Field of the Invention

The present invention relates to the field of testing light emitting diodes (LEDs), and more particularly to a system and method for testing LEDs on a motherboard.

2. Description of Related Art

A light emitting diode (LED) have been applied with commercial products since the 1960s, due to its favorable characteristics. LEDs display high-shake endurance, long-service life, small power consumption and little heat production. As such, the LED can be applied for daily usage in a variety of ways, such as: household appliances, indicative illumination for equipments or as light sources. In recent years, a printed circuit board (PCB), such as a motherboard, has been made in such a way that it contains one or more LEDs. The one or more LEDs is/are used as external signals, internal diagnostics and for purposes of other suitable applications.

In order to verify whether each LED located on the PCB works in a normal state, it is usually necessary to power up the PCB and manually test the characteristics of the LEDs. However, in situations of manual testing, problems may occur in LED production lines. First of all, manual testing may likely destroy the PCB, if the voltage passing through the PCB gets too high. Secondly, the increase in complexity and the decrease in accuracy of LEDs may also lead to problems. For example, if a human operator testing the characteristics of LEDs only tests the LEDs by viewing the luminance of the LEDs, then the test would likely be inaccurate and error-prone because of man-made negligence in the manual testing process. More importantly, if multiple LEDs are being used on the PCB, the manual testing requirements may become problematic and severely inefficient, resulting in a decrease in productivity.

Therefore, what is needed is a system and method for testing LEDs on a motherboard, particularly, one which can conveniently test the characteristics of the LEDs located on the motherboard. A system and method for testing LEDs on a motherboard, one that can take the place of manual testing, can increase the accuracy of the test results and the efficiency of the test productivity.

### SUMMARY OF THE INVENTION

A system for testing light-emitting diodes (LEDs) on a motherboard includes: a motherboard, an insulating plate, a circuit board and a computer. The insulating plate covers the motherboard, and is configured with optical fibers to induce beams sourced from the LEDs and to transmit beams to a circuit board. The circuit board is connected to the insulating plate by the optical fibers. The circuit board includes at least one photoresistor configured for sensing the beams sourced from the LEDs to obtain influence values and for transmitting the influence values to a computer. The computer is configured for controlling the LEDs, to power on or power off, by controlling luminous intensities of the LEDs. This computer configuration is useful for detecting whether the influence values are within a photosensitive range when the LEDs are powered on. The computer is further configured for detecting whether resistance values of all and/or at least one photoresistor are equal to a dark resistance when the LEDs are powered off. The computer is also further configured for reporting test results.

A method for testing light-emitting diodes (LEDs) on a motherboard includes: covering the motherboard with a insulating plate and connecting the LEDs of the motherboard to a circuit board via optical fibers of the insulating plate, wherein the circuit board comprises at least one photoresistor; obtaining an influence value of each of the LEDs; detecting whether a resistance value of a given photoresistor is equal to a corresponding dark resistance generated when a respective LED is powered off; detecting whether the influence value of each of the LEDs is within a photosensitive range of the at least one photoresistor, when each of the LEDs is powered on; and reporting test results denoting that each of the LEDs passes the test, if the resistance value of each of the or at least one photoresistor is equal to a corresponding dark resistance and the influence value of each of the LEDs is within the photosensitive range; or reporting test results denoting that each of the LEDs fails the test, if the resistance value of each of the or at least one photoresistor is not equal to the corresponding dark resistance or if the influence value of each of the LEDs is not in the photosensitive range.

Other novel features of the indicated invention will become more apparent from the following detailed description of the preferred embodiment when taken in conjunction with the accompanying drawings.

### BRIEF DESCRIPTION OF THE DRAWINGS

FIG. 1 is a schematic diagram of a system for testing light emitting diodes (LEDs) on a motherboard in accordance with one embodiment;

FIG. 2 is a schematic diagram illustrating a proximateness (or a connection) between one of a given number of LEDs and optical fibers via one of the multi-holes of FIG. 1;

FIG. 3 is a schematic graph illustrating a variable voltage of at least one photoresistor in a circuit board of FIG. 1;

FIG. 4 is a schematic diagram of software function modules of a computer of FIG. 1; and

FIG. 5 is a flowchart of a preferred method for testing LEDs on a motherboard in accordance with another embodiment.

### DETAILED DESCRIPTION OF THE INVENTION

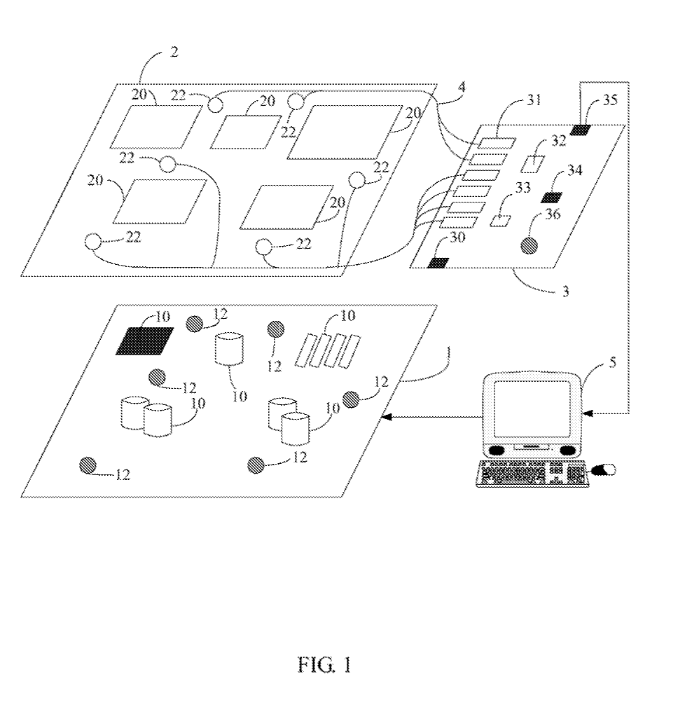

FIG. 1 is a schematic diagram of a system for testing light emitting diodes (LEDs) on a motherboard (hereinafter, “the system”) in accordance with one embodiment. The system typically includes: a motherboard 1, an insulating plate 2, a circuit board 3, and a computer 5. The insulating plate 2 is positioned on the motherboard 1 and is overlaying with optical fibers 4. The optical fibers 4 in FIG. 1 are simply indicated, and the real size of each of the optical fibers 4 is neglected. Actually each of the optical fibers 4 is configured with a pipeline. The real size of each of the optical fibers 4 approximately equals the size of the LEDs. The insulating plate 2 is connected with the circuit board 3 via the optical fibers 4. In the preferred embodiment, the motherboard 1 can be incorporated into the computer 5. In an alternative embodiment, the motherboard 1 is external to the computer 5.

The motherboard 1 mainly includes multiple numbers of components 10 such as a CPU, resistors, capacitors, pins, and one or more LEDs 12. In the preferred embodiment, each of the LEDs 12 may be a power LED, a hard-disk-drive LED, or a key-lock LED. The power LED lights up when the computer 5 is powered on. The hard-disk-drive LED lights up when the hard disk drive is being accessed and the light may appear to flicker as the disk exchanges data with other device (i.e., CPU or memory). The key-lock function is provided to lock the computer 5 with a mechanical key, in order to prevent the computer 5 from booting when the computer 5 is locked. There are multi-holes 20, 22 on the insulating plate 2 corresponding to positions of the components 10 and the given number of the LEDs 12. The insulating plate 2 covers the motherboard 1 while the multi-holes 20, 22 thereof provide passways allowing the corresponding components 10, 12 such as the resistors, the capacitors, the pins, and the LEDs 12 to pass therethrough. For example, in order to have the insulating plate 2 usefully cover the motherboard 1 the insulating plate 2 has the multi-holes 20, 22 for the insertion of the components 10 and of the LEDs 12. The size of the insulating plate 2 is designed according to the size of the motherboard 1.

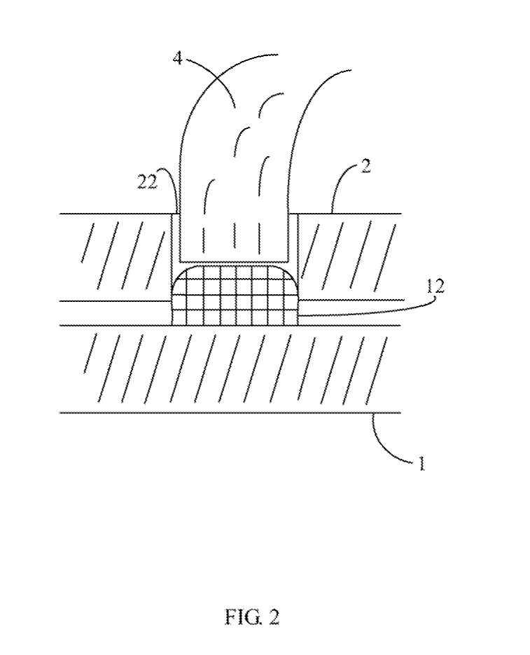

The circuit board 3 configured with a power switch 30, one or more photoresistors 31, an analog to digital converter 32 (hereinafter referred to as A/D converter 32), a level changer 33, a processor 34, a serial port 35 and an LED lamp 36. Each of the optical fibers 4 is posited on a corresponding portion of the insulating plate 2 and is terminated proximately to a corresponding one of the multi-holes 22. FIG. 2 is a schematic diagram illustrating a proximateness (or a connection) of one of the LEDs 12 and the optical fibers 4 via one of the multi-holes 22. The optical fibers 4 are configured for functions of inducing beams sourced from the given number of LEDs 12 and transmitting the beams to the circuit board 3. When the insulating plate 2 is positioned on the motherboard 1, the optical fibers 4 proximate to (or contact) a given number of LEDs 12 with corresponding ends thereof thereby forming corresponding number of beams inside the optical fibers 4 upto a corresponding number of photoresistors 31, i.e., the optical fibers 4 guide the beams originated from the LEDs 12 to the photoresistors 31. In the preferred embodiment, the number of the photoresistors 31 is greater than or equal to the number of the LEDs 12.

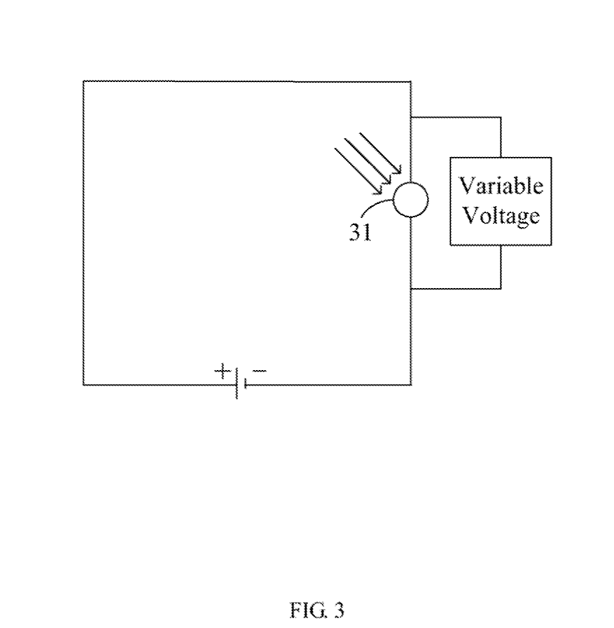

When the power light 30 lights up, the given number of the photoresistors 31 senses the beams sourced from the given number of the LEDs 12 via the optical fibers 4 and generates analog signals according to the beams occur. The photoresistors 31 are manufactured with photosensing materials, such as: cadmium sulfide, lead sulfide, or indium antimonide. The given number of the photoresistors 31 converts the luminance of the given number of the LEDs 12 to electrical signals. The resistance value of the given number of the photoresistors 31 may be reduced if the luminous intensity of the given number of the LEDs 12 is enhanced. Different fabrication technologies of the given number of the photoresistors 31 have different resistance properties. The given number of the photoresistors 31 contains a light resistance and a dark resistance. For example, if the type of the given number of the photoresistors 31 is “GL3516”, the light resistance of the given number of the photoresistors 31 is “5 to 10 kilo-Ohms” and the corresponding dark resistance is “0.6 Megohms”. The light resistance is a resistance value of the given number of the photoresistors 31, irradiated for thirty-one hours (in a range from 40 Luminas to 60 Luminas) and then irradiated for two hours with a 10 Luminas light (the color temperature of the light is lower than 285K). The dark resistance is a resistance value after the given number of the photoresistors 31 ends a 10 Luminas light irradiation after ten seconds. When given a designated voltage, the current of each of the given number of the photoresistors 31 changes, along with the resistance value of each of the given number of the photoresistors 31 and the voltage of the given number of at least one photoresistors 31 changes too. That is, the given number of the photoresistors 31 has a variable voltage. FIG. 3 is a schematic graph illustrating the variable voltage of the given number of the photoresistors 31. The variable voltage is a photosensitive range of the given number of the photoresistors 31. In the preferred embodiment, all of the given numbers of the photoresistors 31 are manufactured with the same materials and fabrication technologies.

The A/D converter 32 is configured for conversion of the analog signals into influence values, that is, each of the photoresistors 31 has a corresponding influence value. For the different electronic properties, the level changer 33 is configured for adjusting the power levels to be compatible to the inputs of the processor 34. The processor 34 is configured for processing the power levels to obtain processed influence values and for transmitting the processed influence values to the level changer 33, to change electronic properties between the processor 34 and the serial port 35. The level changer 33 transmits the processed influence values to the computer 5 via the serial port 35. In the preferred embodiment, the processor 34 can be a microprocessor and the type of serial port 35 can be “RS-232”.

The computer 5 is configured for receiving the processed influence values, for controlling the power on or power off function of the given number of at least one LED 12 and for determining test results according to the processed influence values. The LED lamp 36 is configured for emitting different color lights to indicate the test results.

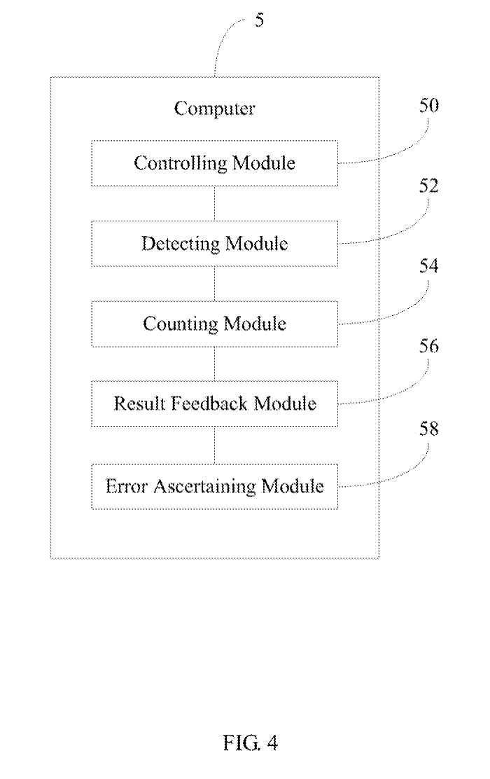

FIG. 4 is a schematic diagram of software function modules of the computer 5 in FIG. 1. The computer 5 typically includes: a controlling module 50, a detecting module 52, a counting module 54, a result feedback module 56 and an error ascertaining module 58.

The controlling module 50 is configured for controlling the given number of the LEDs 12 to power on or power off, by controlling the luminous intensity of the given number of the LEDs 12. This configuration of controlling module 50 is for controlling the given number of the photoresistors 31 in sensing the beams sourced from the given number of the LEDs 12 and obtaining the analog signals according to the beams, as well as for controlling the circuit board 3 in conversion of the analog signals to the influence values.

The detecting module 52 is configured for detecting whether the influence values are within the photosensitive range of the given number of the photoresistors 31, when each of the LEDs 12 is powered on and for calculating the resistance value of each of the photoresistors 31. The counting module 54 is configured for counting the number of photosensitive photoresistors whose influence values are in the photosensitive range. The detecting module 52 is further configured for determining and reporting the detected test results. Result determination is done by comparing the number of the photosensitive photoresistors to the number of the given number of the LEDs 12 on the motherboard 1 and by detecting whether the resistance value of each of the photoresistors 31 is equal to the dark resistance. In the preferred embodiment, if the voltage of a given number of the photoresistors 31 does not change when a given number of the LEDs 12 is powered off, then the detecting module 52 can detects the resistance value of each of the photoresistors 31, where each value is equal to the dark resistance. The result feedback module 56 is configured for transmitting the test results to the circuit board 3. The LED lamp 36 is configured with different LEDs with different light color for each LED. Therefore, the LED lamp 36 is configured for emitting different colors of light to indicate the test results. For example, if the resistance values of all of the given number of the photoresistors 31 are equal to the dark resistance and the influence value of each of the LED 12 is within the photosensitive range, then the LED lamp 36 emits a first color light (e.g., a green light) indicating that all of the LEDs 12 are in a workable state, namely, the given number of the LEDs 12 passes the test. Otherwise, if the resistance values of all of the photoresistors 31 are not equal to the dark resistance or the influence value of each of the LEDs 12 is not within the photosensitive range, the LED lamp 36 emits a second color light (e.g., a red light) indicating that any of the given number of the LEDs 12 is in an unworkable state, namely, the given number of the LEDs 12 of the motherboard 1 fails the test.

The error ascertaining module 58 is configured for ascertaining that each of the LEDs 12 on the motherboard 1 is in an unworkable state according to the test results. In the preferred embodiment, the error ascertaining module 58 can number each of the given number of the LEDs 12 and the given number of the photoresistors 31 in advance. In an alternative embodiment, a multiplexer is used for ordered selection of the given number of the LEDs 12 and the given number of the photoresistors 31.

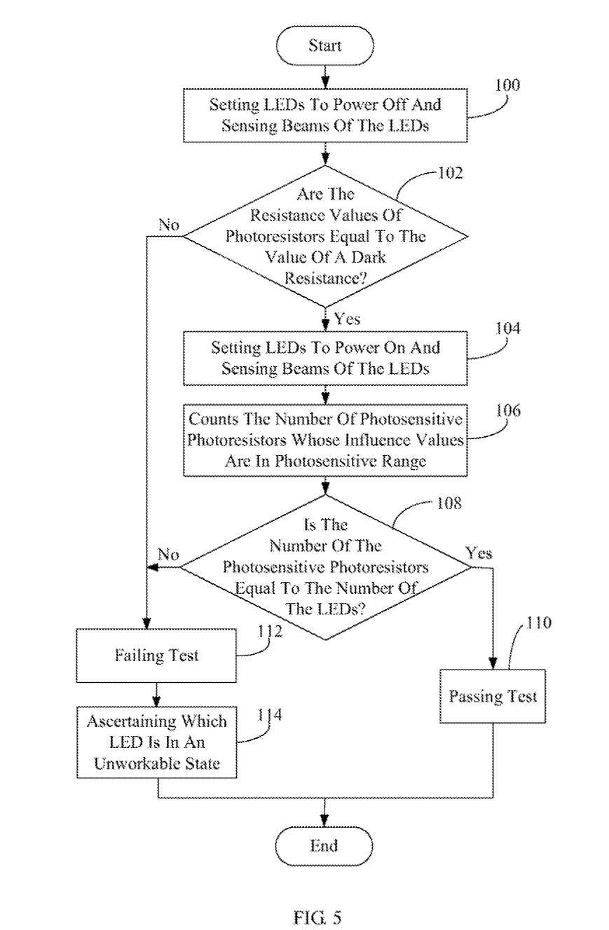

FIG. 5 is a flowchart of a preferred method for testing LEDs on a motherboard, in accordance with another embodiment. Before the test, an operator covers the insulating plate 2 on the motherboard 1, and connects the given number of the LEDs 12 with the given number of the photoresistors 31 via the optical fibers 4. In step S100, the controlling module 50 controls the luminous intensity of each of the given number of the LEDs 12 to set the given number of the LEDs 12 to power off and controls the given number of the photoresistors 31 to sense the beams sourced from the given number of the LEDs 12 to obtain the analog signals. Meanwhile, the circuit board 3 performs the following steps that includes: the A/D converter 32 converting the analog signals to influence values; the level changer 33 adjusting the power levels to be compatible to the inputs of the processor 34; and the processor 34 obtaining processed influence values and transmitting the processed influence values to the level changer 33; following which, at the step of level changer 33 the electric properties change.

In step S102, the detecting module 52 receives the processed influence values, calculates resistance values of all the photoresistors 31 according to the processed influence values and detects whether the resistance values are equal to the dark resistance. For example, the detecting module 52 detects whether the voltage of each of the given number of the photoresistors 31 is changed.

If the resistance values are equal to the dark resistance, in step S104, the controlling module 50 controls the luminous intensity of the given number of the LEDs 12 to set the given number of the LEDs 12 to power on. The controlling module 50 also controls the given number of the photoresistors 31 to sense the beams sourced from the LED 12, to obtain the analog signals, to process the analog signals and obtain the processed influence values by utilizing the same method as described in step S100.

In step S106, the detecting module 52 detects whether the processed influence values, as described in step S104, are within the photosensitive range. The counting module 54 counts the number of the photosensitive photoresistors whose processed influence values are within the photosensitive range.

In step S108, the detecting module 52 determines the test results by detecting whether the number of the photosensitive photoresistors is equal to the number of the given number of the LEDs 12. The result feedback module 56 transmits the test results to the circuit board 3.

If the number of the photosensitive photoresistors is equal to the number of the given number of the LEDs 12, namely, if all of the given number of the LEDs 12 pass the test, in step S110, the LED lamp 36 emits a first color light (i.e., a green light) to indicate the test results.

Otherwise, if the number of the photosensitive photoresistors is not equal to the number of the given number of the LEDs 12, namely, if any of the given number of the LEDs 12 fail the test, in step S112, the LED lamp 36 emits a second color light (i.e., a red light) to indicate the test results.

In step S114, the error ascertaining module 58 ascertains which LED on the motherboard 1 is in an unworkable state according to the given number of the LEDs 12 and the given number of the photoresistors 31, which are numbered in advance.

In the preferred embodiment, an operator can also set the given number of the LEDs 12 to power on at first, and then set the given number of the LED 12s to power off, if the number of the photosensitive photoresistors is equal to the number of the given number of the LEDs 12. Finally, the detecting module 52 determines the test results by detecting whether the resistance values are equal to the dark resistance.

It is to be understood, however, that even though numerous characteristics and advantages of the indicated invention have been set forth in the foregoing description, together with details of the structure and function of the invention, the disclosure is illustrative only and changes may be made in details, especially in matters of shape, size and arrangement of parts within the principles of the invention to the full extent indicated by the broad general meaning of the terms in which the appended claims are expressed.

What is claimed is:

1. A system for testing light-emitting diodes (LEDs) on a motherboard, comprising:
an insulating plate positioned on the motherboard and configured with optical fibers for inducing beams sourced from the LEDs and transmitting the beams;
a circuit board receiving the beams transmitted from the LED's, the circuit board being connected to the insulating plate with the optical fibers, the circuit board comprising at least one photoresistor configured for sensing the beams sourced from the LEDs to obtain influence values and for transmitting the influence values; and
a computer receiving the influence values from the circuit board, the computer being configured for controlling the LEDs to power on or power off by controlling luminous intensities of the LEDs, the computer configured for detecting whether the influence values are within a photosensitive range when the LEDs are powered on, the computer configured for detecting whether resistance values of all the at least one photoresistor are equal to a dark resistance when the LEDs are powered off, and the computer configured for reporting test results.

2. The system for testing LEDs on a motherboard as described in claim 1, wherein the circuit board further comprises:
an A/D converter configured for converting the analog signals into influence values;
a level changer configured for adjusting power levels of the influence values to be compatible as an input of a processor; and
the processor configured for processing the influence values to obtain the processed influence values, and the processor configured for transmitting the processed influence values to the level changer for changing electric properties between the processor and a serial port.

3. The system for testing LEDs on a motherboard as described in claim 1, wherein the circuit board further comprising an LED lamp configured for emitting different color lights to indicate the test results.

4. The system for testing LEDs on a motherboard as described in claim 1, wherein the computer comprises:
a controlling module configured for controlling the luminous intensities of the LEDs, for controlling the given number of at least one photoresistor to sense the beams sourced from the LEDs and obtain the influence values, and for controlling the circuit board to process the influence values;
a detecting module configured for determining whether all the LEDs pass or fail the test by detecting whether the influence values are within the photosensitive range when the LEDs are powered on, by detecting whether resistance values of all the at least one photoresistor are equal to the dark resistance when the LEDs are powered off and by comparing the number of photosensitive photoresistors with the number of the LEDs and for reporting the test results;
a counting module configured for counting the number of the photosensitive photoresistors whose influence values are within the photosensitive range when the LEDs are powered on;
a result feedback module configured for transmitting the test results to the circuit board; and
an error ascertaining module configured for ascertaining whether each of the LEDs is in a workable state or in an unworkable state according to the test results.

5. The system for testing LEDs on a motherboard as described in claim 1, wherein the insulating plate comprises multi-holes corresponding to a plurality of components on the motherboard and covers on the motherboard via the multi-holes.

6. The system for testing LEDs on a motherboard as described in claim 1, wherein the insulating plate comprises optical fibers within a pipeline for each of the LEDs and each of the LEDs connected to each of the given number of at least one photoresistor via the optical fibers respectively.

7. The system for testing LEDs on a motherboard as described in claim 6, wherein the number of the given number of at least one photoresistor is equal to the number of the LEDs on the motherboard.

8. A method for testing light-emitting diodes (LEDs) on a motherboard, the method comprising:
covering the motherboard with a insulating plate and connecting the LEDs of the motherboard to a circuit board via optical fibers of the insulating plate, wherein the circuit board comprises at least one photoresistor;
obtaining an influence value of each of the LEDs;
detecting whether resistance values of the given number of at least one photoresistor are equal to corresponding dark resistances when each of the LEDs are powered off;
detecting whether the influence value of each of the LEDs is within a photosensitive range of the at least one photoresistor when each of the LEDs is powered on; and
reporting test results denoting that each of the LEDs passes the test, if the resistance values of all of the given number of at least one photoresistor are equal to corresponding dark resistances and the influence value of each of the LEDs is within the photosensitive range; or
reporting test results denoting that each of the LEDs fails the test, if the resistance values of all of the at least one photoresistor are not equal to corresponding dark resistances or the influence value of each of the LEDs is not in the photosensitive range.

9. The method for testing LEDs on a motherboard as described in claim 8, further comprising steps of:
setting the LEDs to power off by controlling luminous intensities of the LEDs;
sensing beams sourced from the LEDs to obtain analog signals via the given number of at least one photoresistor;
converting the analog signals to influence values;
processing the influence values by a processor;
changing electric properties between the processor and a serial port of the circuit board;
transmitting the influence values to a computer via the serial port; and
calculating resistance values of the given number of at least one photoresistor.

10. The method for testing LEDs on a motherboard as described in claim 8, further comprising steps of:
setting the LEDs to power on by controlling luminous intensities of the LEDs;
sensing beams sources from the LEDs to obtain analog signals via the given number of at least one photoresistor;
converting the analog signals to influence values;
processing the influence values by a processor;
changing electric properties between the processor and a serial port of the circuit board;
transmitting the influence values to a computer via the serial port;
counting the number of photosensitive photoresistors whose influence values are in a photosensitive range of the given number of at least one photoresistor when each of the LEDs is powered on; and
determining whether the influence value of all of the LEDs is within a photosensitive range by comparing the number of the photosensitive photoresistors with the number of the LEDs.

11. The method for testing LEDs on a motherboard as described in claim 8, further comprising steps of:
transmitting the test results to the circuit board; and
indicating the test results with different color lights in an LED lamp of the circuit board.

12. The method for testing LEDs on a motherboard as described in claim 8, further comprising a step of:
ascertaining each of the LEDs on the motherboard is in a workable state or in an unworkable state according to the test results.
